(19) United States
(12) Patent Application Publication
(10) Pub. No.: US 2015/0262997 A1
(43) Pub. Date: Sep. 17, 2015

(54) SWITCHING POWER SUPPLY

(71) Applicant: Kabushiki Kaisha Toshiba, Tokyo (JP)

(72) Inventors: Yusuke Sato, Sagamihara-shi (JP); Yoshihiro Shitou, Yokohama-shi (JP)

(21) Appl. No.: 14/336,488

(22) Filed: Jul. 21, 2014

(30) Foreign Application Priority Data
Mar. 13, 2014 (JP) 2014-049892

(51) Int. Cl. H01L 27/06; H01L 29/872; H01L 29/20; H05B 33/08; H01L 29/40; H01L 29/16; H02M 3/158; H01L 29/778; H01L 29/45

(52) U.S. Cl. CPC H01L 27/0629; H01L 29/7787; H01L 29/872; H01L 29/2003; H01L 29/452; H01L 29/402; H01L 29/16; H02M 3/158; H05B 33/0815

(57) ABSTRACT

According to one embodiment, a switching power supply includes a first conductor and a second conductor. A first transistor with a floating back gate is provided on the first conductor. A switching transistor includes a source terminal electrically connected to a drain terminal of the first transistor, and a back gate electrically connected to the source terminal. The switching transistor is provided on the second conductor.

### CROSS REFERENCE TO RELATED APPLICATION

This application is based upon and claims the benefit of priority from the prior Japanese Patent Application No. 2014-049892, filed on Mar. 13, 2014, the entire contents of which are incorporated herein by reference.

### FIELD

Embodiments described herein relate to a switching power supply.

### BACKGROUND

Switching power supplies are frequently used for consumer devices and industrial devices. As a switching transistor composing a switching power supply, a silicon power MOSFET (metal oxide semiconductor field effect transistor) or a silicon IGBT (insulated gate bipolar transistor) has been mainly used, but there is a problem that power loss is large.

### BRIEF DESCRIPTION OF THE DRAWINGS

FIG. 1 is a schematic sectional view showing a switching power supply according to a first embodiment,

FIG. 2 is a schematic circuit diagram showing the switching power supply according to the first embodiment,

FIG. 3A is a sectional view showing the GaN FET, and FIG. 3B is a sectional view showing the SBD,

FIG. 4 is a schematic plan view showing the switching power supply according to the first embodiment,

FIG. 5 is a schematic sectional view showing a switching power supply according to a second embodiment,

FIG. 6 is a schematic circuit diagram showing the switching power supply according to the second embodiment,

FIG. 7 is a schematic sectional view showing a switching power supply according to a third embodiment, and.

FIG. 8 is a schematic circuit diagram showing the switching power supply according to the third embodiment.

### DETAILED DESCRIPTION

According to one embodiment, a switching power supply includes a first conductor and a second conductor. A first transistor with a floating back gate is provided on the first conductor. A switching transistor includes a source terminal electrically connected to a drain terminal of the first transistor, and a back gate electrically connected to the source terminal. The switching transistor is provided on the second conductor.

Hereinafter, a plurality of further embodiments will be described with reference to the drawings. In the drawings, the same symbols show the same or similar portions.

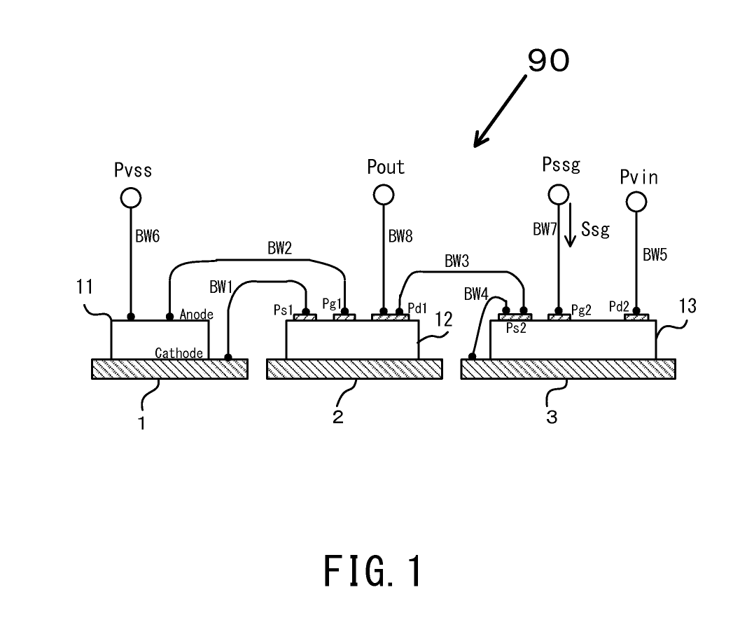

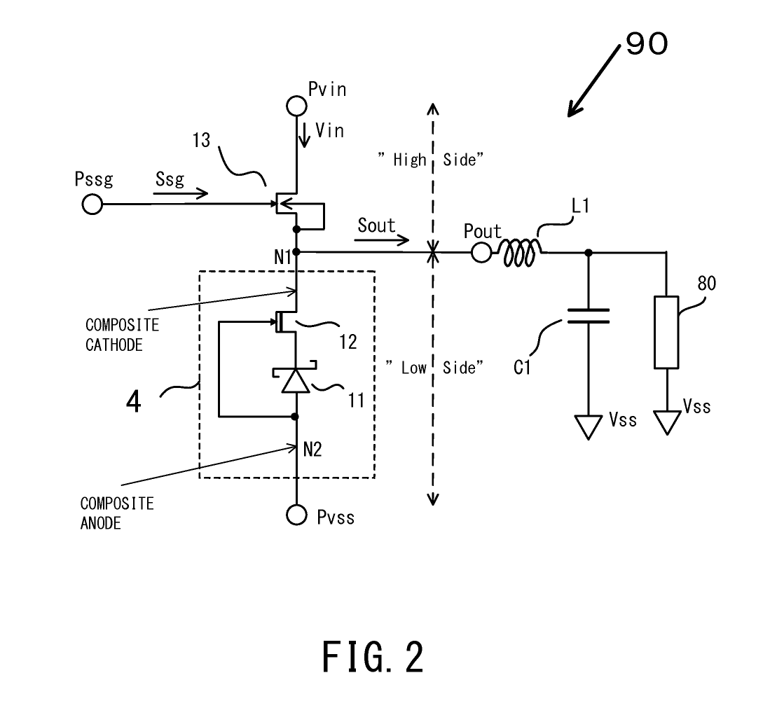

A switching power supply according to a first embodiment will be described with reference to the drawings. FIG. 1 is a schematic sectional view showing the switching power supply. FIG. 2 is a schematic circuit diagram showing the switching power supply. In the embodiment, a GaN FET is used as a switching transistor at a high side, and a rectifier unit composed of a GaN FET and a GaN SBD is used at a low side, to reduce a loss of the switching power supply.

As shown in FIG. 1, a switching power supply 90 includes conductors 1 to 3, a SBD (Schottky barrier diode) 11, a GaN FET 12, a GaN FET 13, bonding wires BW1 to BW8, an output terminal Pout, a control terminal Pssg, an input voltage terminal Pvin, and an ground terminal Pvss. The switching power supply 90 is applied to a lighting device such as an LED lighting, for example.

The conductors 1 to 3 are arranged separately from each other. Here, each of the conductors 1 to 3 is also called a bed of a frame, for example. The SBD 11 is provided on the conductor 1. The GaN FET 12 is provided on the conductor 2. The GaN FET 13 is provided on the conductor 3. Each of the conductors 1 to 3 is any of copper (Cu), nickel (Ni) plated copper (Co), and copper alloy or the like, for example. In the embodiment, the conductor 2 is a first conductor, the conductor 3 is a second conductor, the conductor 1 is a third conductor.

In the SBD 11 that is an SBD chip, a cathode is provided on the conductor 1, and an anode is arranged on an upper face. In the GaN FET 12 that is a GaN FET chip, a back gate is provided on the conductor 2, and a main surface side where an element forming region is provided is arranged on an upper face. In the GaN FET 12, a drain terminal Pd1, a gate terminal Pg1, a source terminal Ps1 are provided on the main surface.

In the GaN FET 13 that is a GaN FET chip, a back gate is provided on the conductor 3, and a main surface side where an element forming region is provided is arranged on an upper face. In the GaN FET 13, a drain terminal Pd2, a gate terminal Pg2, a source terminal Ps2 are provided on the main surface.

The SBD 11 is a GaN SBD, for example. The GaN FET 12 and the GaN FET 13 are each a GaN HEMT (high electron mobility transistor) (R). The SBD 11, the GaN FET 12, and the GaN FET 13 are each a high breakdown voltage device.

A GaN SBD can achieve high breakdown voltage while keeping a low on-resistance compared with a silicon SBD. Compared with a silicon MOSFET, a GaN HEMT can improve an on-resistance, and can perform a high output operation, a high frequency operation, and a high temperature operation, and can greatly reduce switching loss.

One end of the bonding wire BW1 is connected to the conductor 1, and the other end of the bonding wire BW1 is connected to the source terminal Ps1 of the GaN FET 12. One end of the bonding wire BW2 is connected to the anode of the SBD 11, and the other end of the bonding wire BW2 is connected to the gate terminal Pg1 of the GaN FET 12. One end of the bonding wire BW3 is connected to the drain terminal Pd1 of the GaN FET 12, and the other end of the bonding wire BW3 is connected to the source terminal Ps2 of the GaN FET 13. One end of the bonding wire BW4 is connected to the conductor 3, and the other end of the bonding wire BW4 is connected to the source terminal Ps2 of the GaN FET 13.

One end of the bonding wire BW5 is connected to the drain terminal Pd2 of the GaN FET 13, and the other end of the bonding wire BW5 is connected to the input voltage terminal Pvin. One end of the bonding wire BW6 is connected to the anode of the SBD 11, and the other end of the bonding wire BW6 is connected to the ground terminal Pvss. One end of the bonding wire BW7 is connected to the gate terminal Pg2 of the GaN FET 13, and the other end of the bonding wire BW7 is connected to the control terminal Pssg, to transmit a control signal Ssg to the GaN FET 13. One end of the bonding wire BW8 is connected to the drain terminal Pd1 of the GaN FET 12, and the other of the bonding wire BW8 is connected to the output terminal Pout.

As shown in FIG. 2, in the switching power supply 90, the GaN FET 13 is provided at the high side, and a rectifier unit 4 is provided at the low side. The switching power supply 90 is not provided with a control unit (not shown) to generate the control signal Ssg, an inductor L1, and a smoothing capacitor C1 inside. The switching power supply 90 supplies power to a load 80.

Here, one end of the inductor L1 is connected to the output terminal Pout, and the other end of the inductor L1 is connected to one end of the smoothing capacitor C1. The one end of the smoothing capacitor C1 is connected to the other end of the inductor L1 and one end of the load 80 (lighting device, for example), and the other end the smoothing capacitor C1 is connected to a low voltage power supply (ground potential) Vss. The other end of the load 80 is connected to the low voltage power supply (ground potential) Vss. The inductor L1 and the smoothing capacitor C1 stabilize an output signal Sout.

The GaN FET 13 is a switching transistor composed of a normally-off type GaN HEMT. In the GaN FET 13, an input voltage Vin is supplied to the drain through the input voltage terminal Pvin, the control signal Ssg is inputted to the gate through the control terminal Pssg, and the source is connected to a node N1 and the back gate. As a result, in the GaN FET 13, the back gate is set to the same potential as the source. The GaN FET 13 outputs the output signal Sout from the source side (node N1).

In the rectifier unit 4, a composite cathode is connected to the node N1, and a composite anode is connected to a node N2 and the ground terminal Pvss. The rectifier unit 4 includes the GaN FET 12 and the SBD 11. The ground terminal Pvss is set to the low voltage power supply (ground potential) Vss. The rectifier unit 4 is also called a composite diode composed of the SBD 11 and the GaN FET 12.

The GaN FET 12 is a first transistor composed of a normally-on type GaN HEMT. In the GaN FET 12, the drain is connected to the node N1, the gate is connected to the node N2 and the ground terminal Pvss. In the GaN FET 12, the source is not connected to the back gate, and the back gate is under a floating state. In the SBD 11, the cathode is connected to the source of the GaN FET 12, the anode is connected to the node N2, the ground terminal Pvss, and the gate of the GaN FET 12.

In the GaN FET 12, the source terminal Ps1 is not electrically connected to the conductor 2, so that the potentials of the back gate and the source are not made the same potential, but the source terminal Ps1 is electrically connected to the conductor 1. In the GaN FET 13, the source terminal Ps2 is electrically connected to the conductor 3 so that the potentials of the back gate and the source become the same potential.

For this reason, it is possible to make the GaN FET 13 surely perform a normally-off operation.

Being composed of the GaN FET and the GaN SBD, the rectifier unit 4 can greatly reduce parasitic inductance and parasitic resistance, compared with the case of a silicon device.

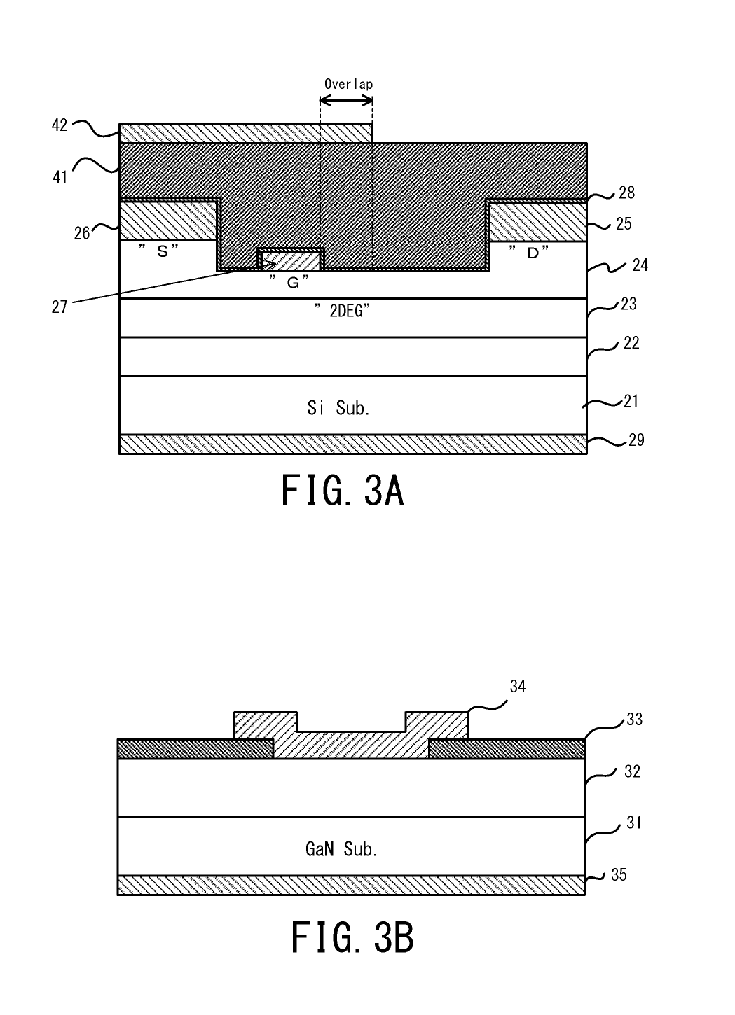

Next, the GaN HEMT and the GaN SBD will be described with reference to FIGS. 3A, 3B. FIG. 3A is a sectional view showing the GaN FET. FIG. 3B is a sectional view showing the GaN SBD. Here, the GaN HEMT shown in FIG. 3A corresponds to the normally-off type GaN FET 13. Regarding the normally-on type GaN FET 12, the description will be omitted.

As shown in FIG. 3A, in the GaN HEMT, a buffer layer 22 is provided on a first main surface of a silicon single crystal substrate 21 with high conductivity. A GaN layer 23 is provided on a first main surface of the buffer layer 22. The buffer layer 22 is provided for mitigating the lattice strain generated between the silicon layer and the GaN layer, AlGaN layer. An AlGaN layer 24 is provided on a first main surface of the GaN layer 23.

Two-dimensional electron gas (“2DEG”) is generated at the AlGaN layer 24 side in the GaN layer 23. In the AlGaN layer 24, an active region is subjected to recess etching. A drain electrode 25 and a source electrode 26 are provided on a first main surface of the AlGaN layer 24. A gate electrode 27 is provided on a first main surface of the recessed AlGaN layer 24. The gate electrode 27 is displaced to the source electrode 26 side (a drain offset structure). An interval between the gate electrode 27 and the drain electrode 25 is made larger than an interval between the gate electrode 27 and the source electrode 26.

An insulating film 28 (silicon nitride film (SiN film), for example) is provided on the AlGaN layer 24, the drain electrode 25, the source electrode 26, and the gate electrode 27. An insulating film 41 is provided on the insulating film 28. A field plate 42 extending to the drain electrode 25 side is provided on the insulating film 41, so as to cover the source electrode 26 and the gate electrode 27 through the insulating film 41. A back gate electrode 29 is provided on a second main surface (back side) opposite to the first main surface of the silicon single crystal substrate 21.

Using the drain offset structure, the field plate 42, and so on, the GaN FET 13 can achieve a breakdown voltage of 600 V, for example.

As shown in FIG. 3B, in the GaN SBD, a GaN layer 32 with low impurity concentration is provided on a first main surface of a GaN substrate 31 with high impurity concentration. An insulating film 33 having an opening portion (not shown) is provided on a first main surface of the GaN layer 32. On the GaN layer 32 and the insulating film 33, an anode electrode 34 is provided, which covers the opening portion and extends onto the insulating film 33 at the both ends of the opening portion (so-called field plate structure). A cathode electrode 35 is provided on a second main surface (back side) opposite to the main surface of the GaN substrate 31.

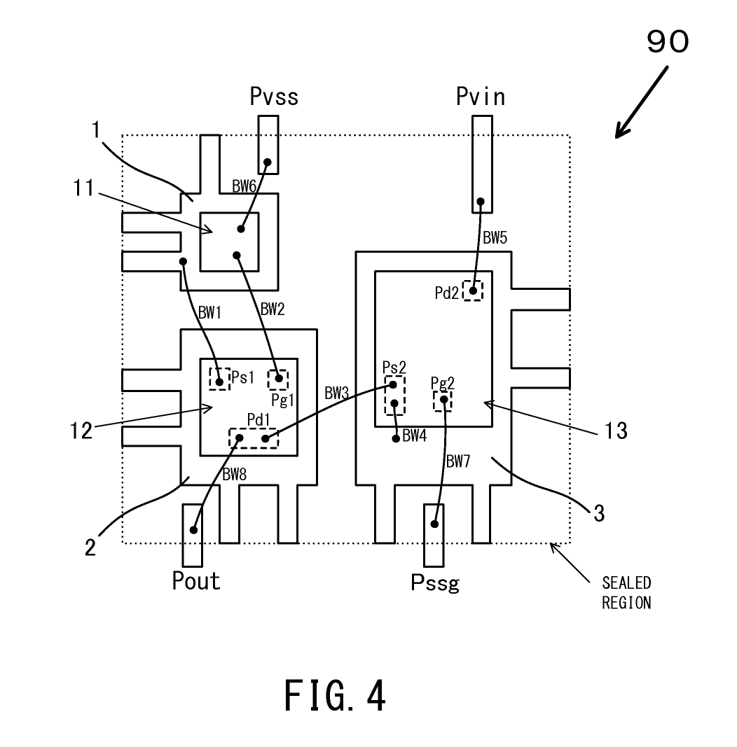

Next, a planar structure of the switching power supply will be described with reference to FIG. 4. FIG. 4 is a schematic plan view showing the switching power supply. Here, the description of the portions duplicated with the description of FIG. 1 will be omitted.

As shown in FIG. 4, the conductors 1 to 3, the SBD 11, the GaN FET 12, the GaN FET 13, and the bonding wires BW1 to BW8 are sealed. Inner lead portions of the output terminal Pout, the control terminal Pssg, the input voltage terminal Pvin, and the ground terminal Pvss are sealed, and outer lead portions of them are exposed. Here, a length of the bonding wire BW5 is shortened, in order to reduce the parasitic inductance component. When the length of the bonding wire BW5 increases, the parasitic inductance component increases, and thereby ripple which is generated at the time of switching operation increases.

As described above, in the switching power supply of the embodiment, the conductors 1 to 3, the SBD 11, the GaN FET 12, the GaN FET 13, the bonding wires BW1 to BW8, the output terminal Pout, the control terminal Pssg, the input voltage terminal Pvin, and the ground terminal Pvss are provided. The GaN FET 13 is provided at the high side, and the rectifier unit 4 composed of the SBD 11 and the GaN FET 12 is provided at the low side. The SBD 11 is a GaN SBD. The GaN FET 12 is a normally-on type GaN HEMT, and the back gate is floating. The SBD 11 is provided on the conductor 1, and the GaN FET 12 is provided on the conductor 2, so that the cathode of the SBD 11 and the back gate of the GaN FET 12 do not become the same potential. The GaN FET 13 is a normally-off type GaN HEMT, and the back gate is set to the same potential as the source. The conductor of the device whose two terminals should be made to the same potential, and the conductor of the device which should be made otherwise are separated, and thereby, it is possible to make the GaN FET 13 surely perform a normally-off operation. The rectifier unit 4 can reduce the parasitic inductance and the parasitic resistance more than a rectifier unit using a silicon device. Since the GaN FET is used as a switching transistor, reduction in on-resistance, high switching operation, and high output power can be realized, compared with a case using a silicon device.

Consequently, it is possible to reduce power loss more greatly than a switching power supply using a silicon device.

In addition, a GaN SBD is used in the embodiment, but a silicon (Si) SBD may be used instead.

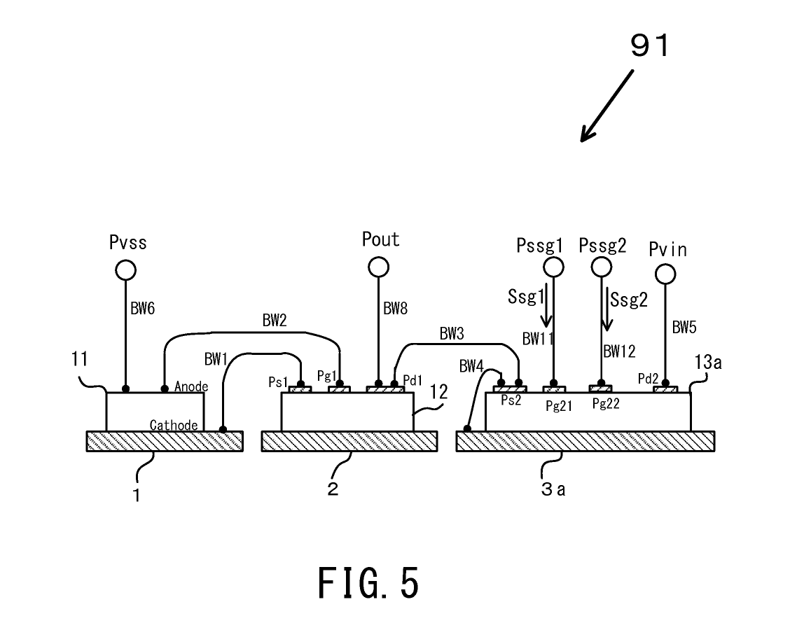

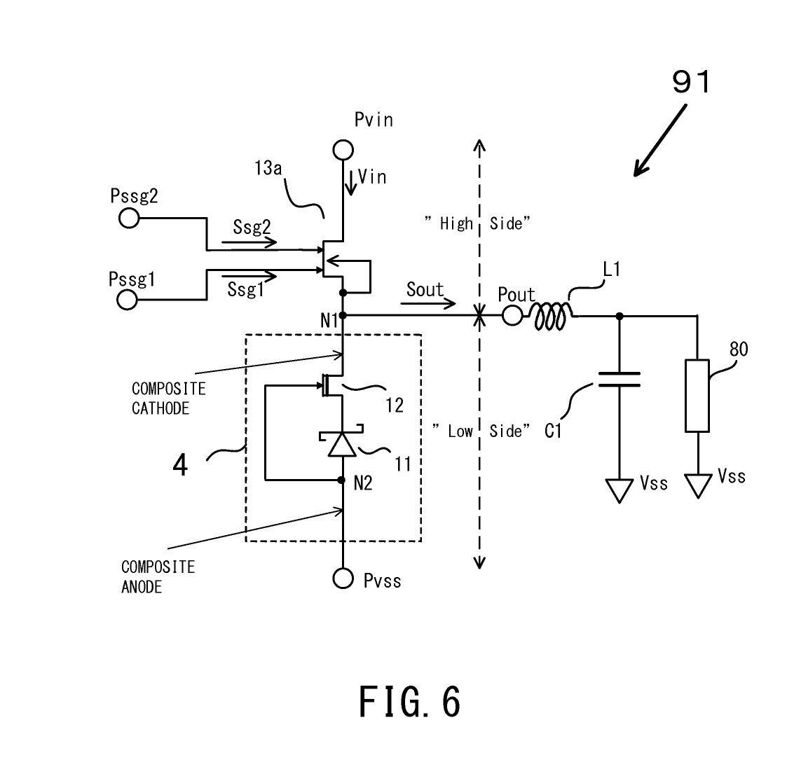

A switching power supply according to a second embodiment will be described with reference to the drawings. FIG. 5 is a schematic sectional view showing the switching power supply. FIG. 6 is a schematic circuit diagram showing the switching power supply. In the embodiment, a switching transistor is made to have a dual gate structure.

Hereinafter, the same symbols are given to the same constituent portions as in the first embodiment, and the description of the portions will be omitted, and only different portions will be described.

As shown in FIG. 5, a switching power supply 91 includes the conductors 1 to 3, the SBD 11, the GaN FET 12, a GaN FET 13a, the bonding wires BW1 to BW5, the bonding wire BW6, the bonding wire BW8, a bonding wire BW11, a bonding wire BW12, the output terminal Pout, a control terminal Pssg1, a control terminal Pssg2, the input voltage terminal Pvin, and the ground terminal Pvss. The switching power supply 91 is applied to a lighting device such as an LED lighting, for example.

In the GaN FET 13a that is a GaN FET chip, a back gate is provided on the conductor 3, and a main surface side where an element forming region is provided is arranged on an upper face. In the GaN FET 13a, the drain terminal Pd2, a gate terminal Pg21, a gate terminal Pg22, the source terminal Ps2 are provided on the main surface. The GaN FET 13a is a high breakdown voltage GaN HEMT, for example. In the GaN FET 13a, a gate electrode portion is different from the first embodiment, but the structure other than that portion is the same as the GaN FET 13 (refer to FIG. 3A) of the first embodiment. In the embodiment, the conductor 2 is a first conductor, the conductor 3a is a second conductor, the conductor 1 is a third conductor.

One end of the bonding wire BW11 is connected to the gate terminal Pg21 of the GaN FET 13a, and the other end of the bonding wire BW11 is connected to the control terminal Pssg1, to transmit a control signal Ssg1 to the GaN FET 13a. One end of the bonding wire BW12 is connected to the gate terminal Pg22 of the GaN FET 13a, and the other end of the bonding wire BW12 is connected to the control terminal Pssg2, to transmit a control signal Ssg2 to the GaN FET 13a.

As shown in FIG. 6, in the switching power supply 91, the GaN FET 13a is provided at the high side, and the rectifier unit 4 is provided at the low side. The switching power supply 91 is not provided with a control unit (not shown) to generate the control signal Ssg1 and the control signal Ssg2, the inductor L1, and the smoothing capacitor C1 inside. The switching power supply 91 supplies power to the load 80.

The GaN FET 13a is a dual gate switching transistor composed of a normally-off type GaN HEMT. In the GaN FET 13a, the input voltage Vin is supplied to the drain through the input voltage terminal Pvin, the control signal Ssg1 is inputted to a first gate through the control terminal Pssg1, the control signal Ssg2 is inputted to a second gate through the control terminal Pssg2, and the source is connected to the node N1 and the back gate. As a result, in the GaN FET 13a, the back gate is set to the same potential as the source. The GaN FET 13a outputs the output signal Sout from the source side (node N1). The GaN FET 13a of a dual gate structure can increase a gain, compared with the GaN FET 13 of a single gate structure of the first embodiment. In addition, even in case that the GaN FET 13a is a normally-on type GaN HEMT, it is possible to reduce the generation of a leak current in the state where a gate voltage is not applied.

As described above, in the switching power supply of the embodiment, the conductors 1 to 3, the SBD 11, the GaN FET 12, the GaN FET 13a, the bonding wires BW1 to BW5, the bonding wire BW6, the bonding wire BW8, the bonding wire BW11, the bonding wire BW12, the output terminal Pout, the control terminal Pssg1, the control terminal Pssg2, the input voltage terminal Pvin, and the ground terminal Pvss are provided. The GaN FET 13a is provided at the high side, and the rectifier unit 4 is provided at the low side. The GaN FET 13a is a normally-off type GaN HEMT of a dual gate structure, and the back gate is set to the same potential as the source. Consequently, the second embodiment has the same effect as the first embodiment.

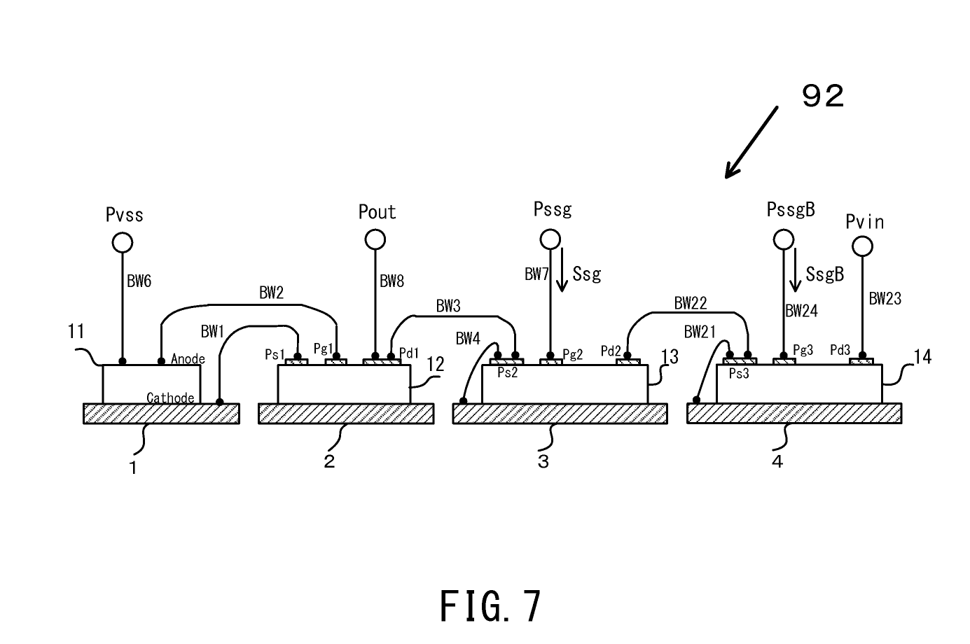

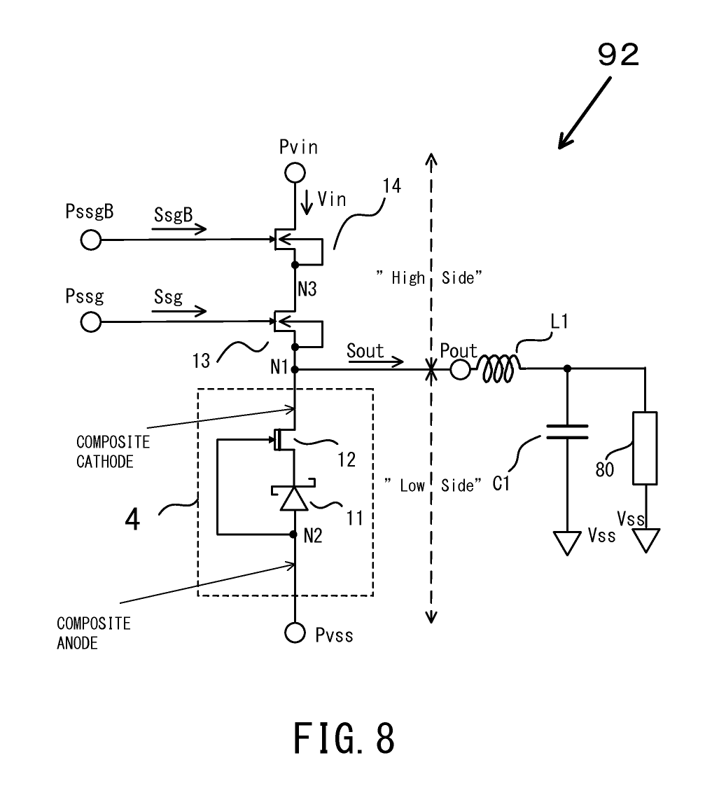

A switching power supply according to a third embodiment will be described with reference to the drawings. FIG. 7 is a schematic sectional view showing the switching power supply. FIG. 8 is a schematic circuit diagram showing the switching power supply. In the embodiment, switching transistors are made to have a two-transistor structure composed of cascode-connected switching transistors.

Hereinafter, the same symbols are given to the same constituent portions as in the first embodiment, and the description of those portions will be omitted, and only different portions will be described.

As shown in FIG. 7, a switching power supply 92 includes the conductors 1 to 3, a conductor 4, the SBD 11, the GaN FET 12, the GaN FET 13, a GaN FET 14, the bonding wires BW1 to BW4, the bonding wires BW6 to BW8, bonding wires BW21 to BW24, the output terminal Pout, the control terminal Pssg, a control terminal PssgB, the input voltage terminal Pvin, and the ground terminal Pvss. The switching power supply 92 is applied to a lighting device such as an LED lighting, for example.

The conductors 1 to 4 are separately arranged from each other. The GaN FET 14 is provided on the conductor 4. The conductor 4 is composed of any of copper (Cu), nickel (Ni) plated copper (Co), and copper alloy or the like, for example.

In the GaN FET 14 that is a GaN FET chip, a back gate is provided on the conductor 4, and a main surface side where an element forming region is provided is arranged on an upper face. In the GaN FET 14, a drain terminal Pd3, a gate terminal Pg3, a source terminal Ps3 are provided on the main surface. The GaN FET 14 is a high breakdown voltage GaN HEMT, for example. The GaN FET 14 has the same structure as the GaN FET 13 of the first embodiment. In the embodiment, the conductor 2 is a first conductor, the conductor 3 is a second conductor, the conductor 4 is a third conductor, the conductor 1 is a fourth conductor.

One end of the bonding wire BW21 is connected to the conductor 4, and the other end of the bonding wire BW21 is connected to the source terminal Ps3 of the GaN FET 14. One end of the bonding wire BW22 is connected to the drain terminal Pd2 of the GaN FET 14, and the other end of the bonding wire BW22 is connected to source terminal Ps3 of the GaN FET 14. One end of the bonding wire BW23 is connected to the drain terminal Pd3 of the GaN FET 14, and the other end of the bonding wire BW23 is connected to the input voltage terminal Pvin. One end of the bonding wire BW24 is connected to the gate terminal Pg3 of the GaN FET 14, and the other end of the bonding wire BW24 is connected to the control terminal PssgB, to transmit a control signal SsgB to the GaN FET 14. The conductor 4 is also called a bed of a frame, for example.

As shown in FIG. 8, in the switching power supply 92, the GaN FET 13 and the GaN FET 14 are provided at the high side, and the rectifier unit 4 is provided at the low side. The switching power supply 92 is not provided with a control unit (not shown) to generate the control signal Ssg and the control signal SsgB, the inductor L1, and the smoothing capacitor C1 inside. The GaN FET 14 and the GaN FET 13 are connected in series between the input voltage terminal Pvin and the node N1 (cascode connection). The switching power supply 90 supplies power to the load 80.

The GaN FET 14 is a switching transistor composed of a normally-off type GaN HEMT. In the GaN FET 14, the input voltage Vin is supplied to the drain through the input voltage terminal Pvin, the control signal Ssg is inputted to the gate through the control terminal PssgB, and the source is connected to a node N3 and the back gate. As a result, in the GaN FET 14, the back gate is set to the same potential as the source. The drain of the GaN FET 13 is connected to the node N3.

Here, the GaN FET 13 and the GaN FET 14 are each a normally-off type GaN HEMT, but each may be a normally-on type GaN HEMT, because they are cascode-connected. In this case, it is possible to reduce the generation of a leak current in the state where a gate voltage is not applied.

As described above, in the switching power supply of the embodiment, the conductors 1 to 4, the SBD 11, the GaN FET 12, the GaN FET 13, the GaN FET 14, the bonding wires BW1 to BW4, the bonding wires BW6 to BW8, the bonding wires BW21 to BW24, the output terminal Pout, the control terminal Pssg, the control terminal PssgB, the input voltage terminal Pvin, and the ground terminal Pvss are provided. The GaN FET 13 and the GaN FET 14 are provided at the high side, and the rectifier unit 4 is provided at the low side. The GaN FET 13 and the GaN FET 14 are each a normally-off type GaN HEMT, and the back gates are set to the same potentials as the sources, respectively. Consequently, the third embodiment has the same effect as the first embodiment.

In addition, the switching power supply of the embodiment is applied to a lighting device, but is not necessarily restricted to this. The switching power supply can be applied to various devices and so on for consumer use and industrial use requiring high frequency and high power which cannot be realized by a silicon device.

While certain embodiments have been described, these embodiments have been presented by way of example only, and are not intended to limit the scope of the inventions. Indeed, the embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A switching power supply, comprising:
a first conductor on which a first transistor having a back gate under a floating state is provided; and
a second conductor on which a switching transistor is provided, the switching transistor having a source terminal electrically connected to a drain terminal of the first transistor and a back gate electrically connected to the source terminal of the switching transistor.

2. The switching power supply according to claim 1, further comprising:
a third conductor on which a diode is provided, wherein
the diode includes a cathode connected to the third conductor, and an anode electrically connected to a ground terminal,
the first transistor includes a source terminal connected to the third conductor through a first bonding wire, and a gate terminal connected to the anode of the diode through a second bonding wire,
a rectifier unit includes the first transistor and the diode,
the switching transistor includes the source terminal connected to the drain terminal of the first transistor through a third bonding wire, and the source terminal connected to the second conductor through a fourth bonding wire, to connect a source to the back gate, a control signal is inputted to a gate terminal, and an input voltage is inputted to a drain terminal, and
an output signal is outputted from the drain terminal side of the first transistor.

3. The switching power supply according to claim 2, wherein
the switching transistor includes a first gate terminal and a second gate terminal, a first control signal is inputted to the first gate terminal, and a second control signal is inputted to the second gate terminal.

4. The switching power supply according to claim 2, wherein
each of the first to third conductors is any of copper (Cu), nickel (Ni) plated copper (Co), and copper alloy.

5. The switching power supply according to claim 1, wherein
the first transistor is a normally-on type GaN FET, and the switching transistor is a normally-off type GaN FET.

6. The switching power supply according to claim 1, wherein
each of the first transistor and the switching transistor has a substrate composed of conductive single crystal silicon.

7. The switching power supply according to claim 2, wherein
the diode is any of a GaN SBD (Schottky barrier diode) and a Si SBD.

8. The switching power supply according to claim 1, wherein
the switching power supply is applied to a lighting device.

9. The switching power supply according to claim 8, wherein
the switching transistor is a high breakdown voltage transistor with a drain offset structure and a field plate.

10. A switching power supply, comprising:
a first conductor on which a first transistor having a back gate under a floating state is provided;
a second conductor on which a first switching transistor is provided, the first switching transistor having a source terminal electrically connected to a drain terminal of the first transistor, and a back gate electrically connected to the source terminal; and
a third conductor on which a second switching transistor is provided, the second switching transistor having a source terminal electrically connected to a drain terminal of the first switching transistor, and a back gate electrically connected to the source terminal of the second switching transistor.

11. The switching power supply according to claim 10, further comprising:
a fourth conductor on which a diode is provided, wherein
the diode includes a cathode connected to the fourth conductor, and an anode electrically connected to an ground terminal,
the first transistor includes a source terminal connected to the fourth conductor through a first bonding wire, and a gate terminal connected to the anode of the diode through a second bonding wire,
a rectifier unit includes the first transistor and the diode,
the first switching transistor includes the source terminal connected to the drain terminal of the first transistor through a third bonding wire, and the source terminal is connected to the second conductor through a fourth bonding wire, to connect a source to the back gate, and a first control signal is inputted to a gate terminal,
the second switching transistor includes the source terminal connected to the drain terminal of the first switching transistor through a fifth bonding wire, and the source terminal connected to the third conductor through a sixth bonding wire so as to connect a source to the back gate, a second control signal is inputted to a gate terminal, and an input voltage is inputted to a drain terminal, and
an output signal is outputted from the drain terminal side of the first transistor.

12. The switching power supply according to claim 11, wherein
each of the first to fourth conductors is any copper (Cu), nickel (Ni) plated copper (Co), and copper alloy.

13. The switching power supply according to claim 10, wherein
the first transistor is a normally-on type GaN FET, and each of the first and second switching transistors is any of a normally-off type GaN FET and a normally-on type GaN FET.

14. The switching power supply according to claim 10, wherein
each of the first transistor and the first and second switching transistors has a substrate composed of conductive single crystal silicon.

15. The switching power supply according to claim 11, wherein
the diode is any of a GaN SBD (Schottky barrier diode) and a Si SBD.

16. The switching power supply according to claim 10, wherein
the switching power supply is applied to a lighting device.

17. The switching power supply according to claim 16, wherein
each of the first and second switching transistors is a high breakdown voltage transistor with a drain offset structure and a field plate.
